(19) United States
(12) Patent Application Publication
(10) Pub. No.: US 2024/0256013 A1
(43) Pub. Date: Aug. 1, 2024

(54) INTEGRATION OF ACTIVE MEMS COOLING SYSTEMS INTO SMART PHONES

(71) Applicant: Frore Systems Inc., San Jose, CA (US)

(72) Inventors: Suryaprakash Ganti, Los Altos, CA (US); Seshagiri Rao Madhavapeddy, La Jolla, CA (US); Prabhu Sathyamurthy, San Jose, CA (US); Nilesh Sudhir Hasabnis, Santa Clara, CA (US); Shekhar Halakatti, Campbell, CA (US)

(21) Appl. No.: 18/424,356

(22) Filed: Jan. 26, 2024

Related U.S. Application Data
(60) Provisional application No. 63/441,723, filed on Jan. 27, 2023.

(51) Int. Cl. G06F 1/20; G06F 1/16; H05K 7/20

(52) U.S. Cl. CPC G06F 1/203; G06F 1/1658; G06F 1/206; H05K 7/20154; H05K 7/20272; G06F 2200/201

(57) ABSTRACT

A mobile phone is described. The mobile phone includes a cover, a circuit board to which a heat-generating structure is coupled, and a cooling system including active cooling cell(s) and contained by the cover. The cover defines an interior of the mobile phone. The circuit board is within the interior. The heat-generating structure is thermally coupled with the cooling system. The active cooling cell(s) utilize vibrational motion to drive a fluid for transferring heat from the heat-generating structure. At least one of the mobile phone includes an interposer, the cover includes a raised portion, or the mobile phone includes a cavity therein. The interposer is coupled to the circuit board and includes a gap such that a first portion of the cooling system thermally coupled with the heat-generating structure resides within the gap. The raised portion of the cover is such that a second portion of the cooling system resides in the raised portion. The cavity includes the cooling system, separates the cooling system from the interior, and is such that the interior is water resistant.

### CROSS REFERENCE TO OTHER APPLICATIONS

This application claims priority to U.S. Provisional Patent Application No. 63/441,723 entitled ACTIVE COOLING SYSTEM FOR SMARTPHONES filed Jan. 27, 2023 which is incorporated herein by reference for all purposes.

### BACKGROUND OF THE INVENTION

As computing devices grow in speed and computing power, the heat generated by the computing devices also increases. Various mechanisms have been proposed to address the generation of heat. Active devices, such as fans, may be used to drive air through large computing devices, such as laptop computers or desktop computers. Passive cooling devices, such as heat spreaders, may be used in smaller, mobile computing devices, such as smartphones, virtual reality devices and tablet computers. However, such active and passive devices may be unable to adequately cool both mobile devices such as smartphones and larger devices such as laptops and desktop computers. Moreover, incorporating cooling solutions into computing devices may be challenging. For example, mobile phones may have an interior cavity that is five millimeters or less in height. Incorporating any cooling system in addition to electrical components, power supplies, speakers, microphones, and/or other components is challenging. Consequently, additional cooling solutions for computing devices are desired.

### BRIEF DESCRIPTION OF THE DRAWINGS

Various embodiments of the invention are disclosed in the following detailed description and the accompanying drawings.

FIGS. 1A-1G depict an embodiment of an active MEMS cooling system including a centrally anchored cooling element.

FIGS. 2A-2B depict an embodiment of an active MEMS cooling system including a centrally anchored cooling element.

FIGS. 3A-3E depict an embodiment of an active MEMS cooling system formed in a tile.

FIG. 4 depicts an embodiment of an active MEMS cooling system as integrated into a mobile phone.

FIGS. 5A-5C depict an embodiment of an active MEMS cooling system as integrated into a mobile phone.

FIG. 6 depicts an embodiment of an active MEMS cooling system as integrated into a mobile phone.

FIG. 7 depicts an embodiment of an active MEMS cooling system as integrated into a mobile phone.

FIG. 8 depicts an embodiment of an active MEMS cooling system as integrated into a mobile phone.

FIG. 9 depicts an embodiment of an active MEMS cooling system as integrated into a mobile phone.

FIG. 10 depicts an embodiment of a method for using an active heat transfer structure.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

As semiconductor devices become increasingly powerful, the heat generated during operations also grows. For example, processors for mobile devices such as smartphones, tablet computers, notebook computers, and virtual reality devices as well as for other computing devices such as servers, can operate at high clock speeds, but produce a significant amount of heat. Because of the quantity of heat produced, processors may run at full speed only for a relatively short period of time. After this time expires, throttling (e.g. slowing of the processor's clock speed) occurs. Although throttling can reduce heat generation, it also adversely affects processor speed and, therefore, the performance of devices using the processors. As technology moves to 5G and beyond, this issue is expected to be exacerbated. Further, other components in a computing device may generate heat. Thus, thermal management is increasingly an issue for computing devices.

Larger computing devices, such as laptop computers, desktop computers, or servers, include active cooling systems. Active cooling systems are those in which an electrical signal is used to drive cooling. An electric fan that has rotating blades is an example of an active cooling system, while a heat spreader is an example of a passive cooling system. When energized, the fan's rotating blades drive air through the larger devices to cool internal components. However, space and other limitations in computing devices limit the use of active cooling systems. Fans are typically too large for mobile and/or thinner devices such as smartphones and tablet or notebook computers. Fans also may have limited efficacy because of the boundary layer of air existing at the surface of the components because they provide a limited airspeed for air flow across the hot surface desired to be cooled, and because they may generate an excessive amount of noise. Fans also have a limited backpressure. Space and power limitations may further restrict the ability to provide electrical connection to active cooling systems. For example, if multiple active cooling systems are used, the connections to the active cooling systems may be required to fit within a small area. In addition, the power consumed by such a cooling system may be desired to be small, particularly for mobile devices. Moreover, space limitations may adversely affect the ability to provide a sufficient flow for cooling computing devices. Consequently, active cooling systems face particular challenges when used in computing devices such as active computing devices. Passive cooling solutions may include components such as a heat spreader and a heat pipe or vapor chamber to transfer heat to a heat exchanger. However, passive cooling solutions may be unable to provide a sufficient amount of heat transfer to remove excessive heat generated. Thus, additional cooling solutions are desired.

A mobile phone is described. The mobile phone includes a cover, a circuit board, and a cooling system. The cover defines an interior portion of the mobile phone. The circuit board is within the interior portion of the mobile phone. A heat-generating structure is coupled to the circuit board. The cooling system includes active cooling cell(s). The heat-generating structure is thermally coupled with the cooling system. The active cooling cell(s) are configured to utilize vibrational motion to drive a fluid for transferring heat from the heat-generating structure. The cooling system is contained by the cover. At least one of the mobile phone includes an interposer, the cover includes a raised portion, or the mobile phone includes a cavity therein. The interposer is coupled to the circuit board and includes a gap configured such that a first portion of the cooling system thermally coupled with the heat-generating structure resides within the gap. The raised portion of the cover is configured such that a second portion of the cooling system resides in the raised portion. The cavity includes the cooling system therein, separates the cooling system from the interior portion of the mobile phone, and is configured such that the interior portion is water resistant.

In some embodiments, the mobile phone includes the interposer. In such embodiments, the mobile phone further includes an additional circuit board. The interposer is coupled to and between the circuit board and the additional circuit board. The additional circuit board may include a circuit board gap aligned with the gap of the interposer. The first portion of the cooling system fits within the circuit board gap.

In some embodiments, the mobile phone includes the cavity. In such embodiments, the cavity is IP68 water resistant. The mobile phone may also include a flex connector coupled with the cooling system such that the cooling system is electrically connected with the interior portion of the mobile phone. In some embodiments, the cooling system has a total height not exceeding 3.5 millimeters. In some embodiments, the total height is not less than 1 millimeter and not exceeding three millimeters. The cooling system may include a first cooling cell and a second cooling cell. The cooling system may also include a heat sink thermally coupled with the heat-generating structure.

The heat-generating structure may include a processor for the mobile phone. The mobile phone may also include a battery. The cooling system is configured to utilize the vibrational motion to transfer the heat from the battery. In some embodiments, each of the active cooling cell(s) includes at least one cooling element configured to undergo the vibrational motion to drive the fluid toward the heat-generating structure. In some embodiments, the cooling element has a first cantilevered arm, a second cantilevered arm, and a central portion between the first cantilevered arm and the second cantilevered arm. The first and second cantilevered arms undergo the vibrational motion. In some embodiments, each of the active cooling cell(s) further includes a top plate and an orifice plate. The top plate has at least one vent therein. The orifice plate includes orifices therein. The cooling element(s) are between the top plate and the orifice plate. The vibrational motion draws the fluid through the vent, directs the fluid past the cooling element, and drives the fluid out of the plurality of orifices.

A mobile phone including front and back covers is described. The interior of the mobile phone is defined between the front cover and the back cover. The mobile phone also includes a heat-generating structure, a circuit board, and a cooling system. The circuit board includes computing components thereon. The cooling system includes active cooling cell(s). The active cooling cell(s) are configured to utilize vibrational motion to drive a fluid for removing heat from the heat-generating structure. At least one of the mobile phone includes an interposer, at least one of the front cover or the back cover includes a raised portion, or the cover includes a cavity therein. The interposer is coupled to the circuit board and includes a gap configured such that a first portion of the cooling system thermally coupled with the heat-generating structure resides within the gap. The raised portion of the cover is configured such that a second portion of the cooling system resides in the raised portion. The cavity includes the cooling system therein, separates the cooling system from an interior portion of the mobile phone including the circuit board, and is configured such that the interior portion is water resistant. In some embodiments, the mobile phone includes the interposer and an additional circuit board. The interposer is coupled to and between the circuit board and the additional circuit board. The additional circuit board includes a circuit board gap aligned with the gap of the interposer such that the first portion of the cooling system fits within the circuit board gap. In some embodiments, the mobile phone includes the cavity, which is IP68 water resistant. The heat-generating structure may be at least one of a processor mounted on the circuit board or a battery.

A method for cooling a mobile phone is described. The mobile phone has a cover defining an interior portion of the mobile phone. The method includes driving active cooling cells in a cooling system of the mobile phone. The mobile phone further includes a circuit board within the interior portion and a heat-generating structure thermally coupled with the cooling system. The active cooling cells are configured to utilize vibrational motion to drive a fluid for transferring heat from the heat-generating structure. At least one of the mobile phone includes an interposer, at least one of the front cover or the back cover includes a raised portion, or the cover includes a cavity therein. The interposer is coupled to the circuit board and includes a gap configured such that a first portion of the cooling system thermally coupled with the heat-generating structure resides within the gap. The raised portion of the cover is configured such that a second portion of the cooling system resides in the raised portion. The cavity includes the cooling system therein, separates the cooling system from an interior portion of the mobile phone including the circuit board, and is configured such that the interior portion is water resistant. In some embodiments, driving further includes driving the active cooling cells such that the vibrational motion is substantially at a structural resonance for the active cooling cells and substantially at a fluidic resonance for the active cooling cells.

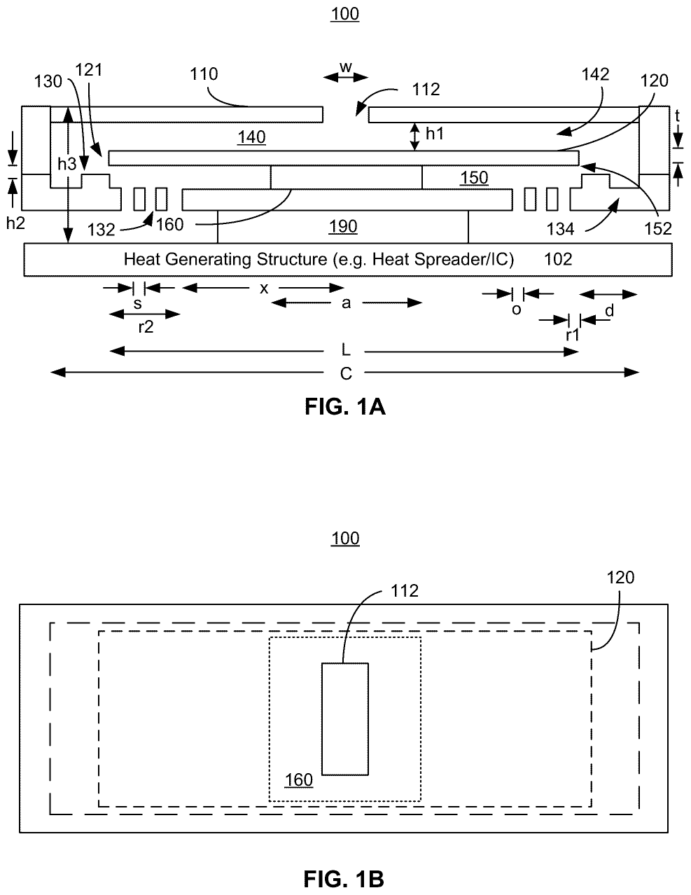

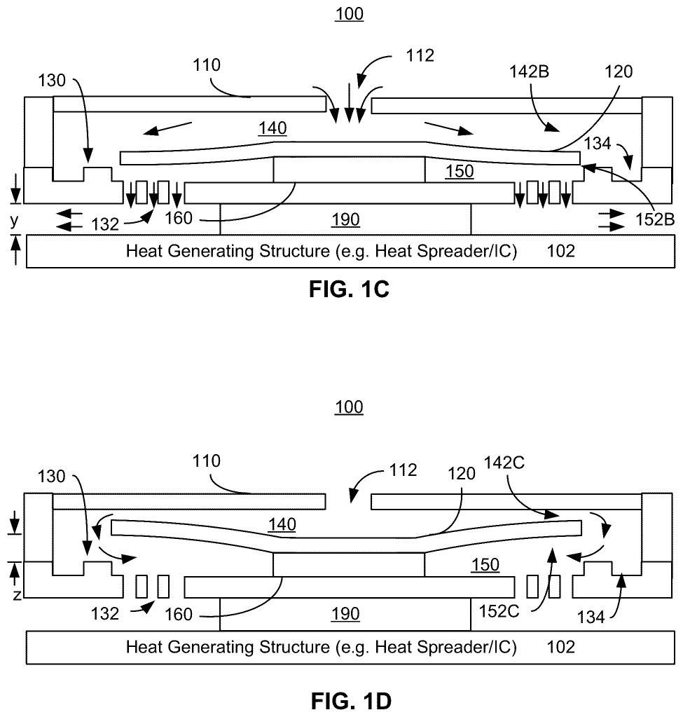

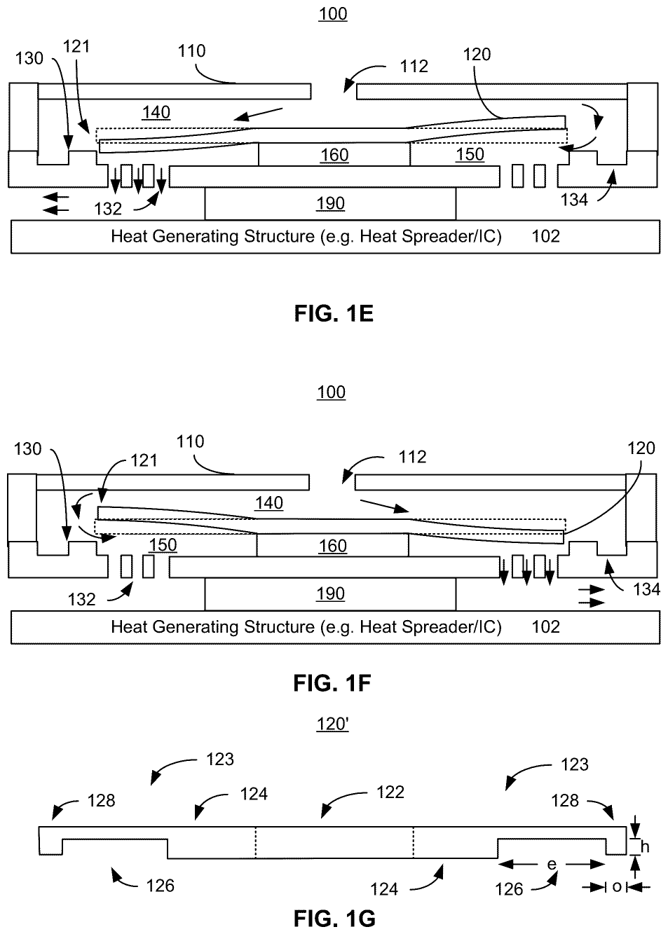

FIGS. 1A-1G are diagrams depicting an exemplary embodiment of active MEMS cooling system 100 usable with heat-generating structure 102 and including a centrally anchored cooling element 120 or 120′. Although termed a cooling system, MEMS system 100 and analogous systems described herein may be considered heat transfer systems and/or fluid transfer systems. Cooling element 120 is shown in FIGS. 1A-1F and cooling element 120′ is shown in FIG. 1G. For clarity, only certain components are shown. FIGS. 1A-1G are not to scale. FIGS. 1A and 1B depict cross-sectional and top views of cooling system 100 in a neutral position. FIGS. 1C-1D depict cooling system 100 during actuation for in-phase vibrational motion. FIGS. 1E-1F depict cooling system 100 during actuation for out-of-phase vibrational motion. Although shown as symmetric, cooling system 100 need not be.

Cooling system 100 includes top plate 110 having vent 112 therein, cooling element 120, orifice plate 130 having orifices 132 and cavities 134 therein, support structure (or “anchor”) 160 and chambers 140 and 150 (collectively chamber 140/150) formed therein. Cooling element 120 is supported at its central region by anchor 160. Although termed a cooling element with respect to FIGS. 1A-1G, cooling element 120 and analogous elements described herein may also be considered actuators, vibrating elements, vibrating components, active components, and/or other terms indicating that the element is configured to undergo vibrational motion when activated (or energized) and/or to drive fluid through a system. Regions of cooling element 120 closer to and including portions of the cooling element's perimeter (e.g. tip 121) vibrate when actuated. In some embodiments, tip 121 of cooling element 120 includes a portion of the perimeter furthest from anchor 160 and undergoes the largest deflection during actuation of cooling element 120. For clarity, only one tip 121 of cooling element 120 is labeled in FIG. 1A. Also shown is pedestal 190 that connects orifice plate 130 to and offsets orifice plate 130 from heat-generating structure 102. In some embodiments, pedestal 190 also thermally couples orifice plate 130 to heat-generating structure 102. In some embodiments, an additional jet channel plate may be present and supported by pedestal 190. Thus orifice plate 130 and/or such a jet channel plate may be part or all of a bottom plate supported by pedestal 190. Thus, multiple plates and/or plate(s) having various structures may be used at the bottom plate for cooling system 100.

FIG. 1A depicts cooling system 100 in a neutral position. Thus, cooling element 120 is shown as substantially flat. For in-phase operation, cooling element 120 is driven to vibrate between positions shown in FIGS. 1C and 1D. This vibrational motion draws fluid (e.g. air) into vent 112, through chambers 140 and 150 and out orifices 132 at high speed and/or flow rates. For example, the speed at which the fluid impinges on heat-generating structure 102 may be at least thirty meters per second. In some embodiments, the fluid is driven by cooling element 120 toward heat-generating structure 102 at a speed of at least forty-five meters per second. In some embodiments, the fluid is driven toward heat-generating structure 102 by cooling element 120 at speeds of at least sixty meters per second. Other speeds may be possible in some embodiments. Cooling system 100 is also configured so that little or no fluid is drawn back into chamber 140/150 through orifices 132 by the vibrational motion of cooling element 120.

Heat-generating structure 102 is desired to be cooled by cooling system 100. In some embodiments, heat-generating structure 102 generates heat. For example, heat-generating structure may be an integrated circuit. In some embodiments, heat-generating structure 102 is desired to be cooled but does not generate heat itself. Heat-generating structure 102 may conduct heat (e.g. from a nearby object that generates heat). For example, heat-generating structure 102 might be a heat spreader or a vapor chamber. Thus, heat-generating structure 102 may include semiconductor component(s) including individual integrated circuit components such as processors, other integrated circuit(s) and/or chip package(s); sensor(s); optical device(s); one or more batteries; other component(s) of an electronic device such as a computing device; heat spreaders; heat pipes; other electronic component(s) and/or other device(s) desired to be cooled. In some embodiments, heat-generating structure 102 may be a thermally conductive part of a module containing cooling system 100. For example, cooling system 100 may be affixed to heat-generating structure 102, which may be coupled to another heat spreader, vapor chamber, integrated circuit, or other separate structure desired to be cooled.

The devices in which cooling system 100 is desired to be used may also have limited space in which to place a cooling system. For example, cooling system 100 may be used in computing devices. Such computing devices may include but are not limited to smartphones, tablet computers, laptop computers, tablets, two-in-one laptops, hand held gaming systems, digital cameras, virtual reality headsets, augmented reality headsets, mixed reality headsets and other devices that are thin. Cooling system 100 may be a micro-electro-mechanical system (MEMS) cooling system capable of residing within mobile computing devices and/or other devices having limited space in at least one dimension. For example, the total height, h3, of cooling system 100 (from the top of heat-generating structure 102 to the top of top plate 110) may be less than 2 millimeters. In some embodiments, the total height of cooling system 100 is not more than 1.5 millimeters. In some embodiments, this total height is not more than 1.1 millimeters. In some embodiments, the total height does not exceed one millimeter. In some embodiments, the total height does not exceed two hundred and fifty micrometers. Similarly, the distance between the bottom of orifice plate 130 and the top of heat-generating structure 102, y, may be small. In some embodiments, y is at least two hundred micrometers and not more than 1.2 millimeter. For example, y may be at least two hundred and fifty micrometers and not more than three hundred micrometers. In some embodiments, y is at least five hundred micrometers and not more than one millimeter. In some embodiments, y is at least two hundred micrometers and not more than three hundred micrometers. Thus, cooling system 100 is usable in computing devices and/or other devices having limited space in at least one dimension. However, nothing prevents the use of cooling system 100 in devices having fewer limitations on space and/or for purposes other than cooling. Although one cooling system 100 is shown (e.g. one cooling cell), multiple cooling systems 100 might be used in connection with heat-generating structure 102. For example, a one or two-dimensional array of cooling cells might be utilized.

Cooling system 100 is in communication with a fluid used to cool heat-generating structure 102. The fluid may be a gas or a liquid. For example, the fluid may be air. In some embodiments, the fluid includes fluid from outside of the device in which cooling system 100 resides (e.g. provided through external vents in the device). In some embodiments, the fluid circulates within the device in which cooling system 100 resides (e.g. in an enclosed device).

Cooling element 120 can be considered to divide the interior of active MEMS cooling system 100 into top chamber 140 and bottom chamber 150. Top chamber 140 is formed by cooling element 120, the sides, and top plate 110. Bottom chamber 150 is formed by orifice plate 130, the sides, cooling element 120 and anchor 160. Top chamber 140 and bottom chamber 150 are connected at the periphery of cooling element 120 and together form chamber 140/150 (e.g. an interior chamber of cooling system 100).

The size and configuration of top chamber 140 may be a function of the cell (cooling system 100) dimensions, cooling element 120 motion, and the frequency of operation. Top chamber 140 has a height, h1. The height of top chamber 140 may be selected to provide sufficient pressure to drive the fluid to bottom chamber 150 and through orifices 132 at the desired flow rate and/or speed. Top chamber 140 is also sufficiently tall that cooling element 120 does not contact top plate 110 when actuated. In some embodiments, the height of top chamber 140 is at least fifty micrometers and not more than five hundred micrometers. In some embodiments, top chamber 140 has a height of at least two hundred and not more than three hundred micrometers.

Bottom chamber 150 has a height, h2. In some embodiments, the height of bottom chamber 150 is sufficient to accommodate the motion of cooling element 120. Thus, no portion of cooling element 120 contacts orifice plate 130 during normal operation. Bottom chamber 150 is generally smaller than top chamber 140 and may aid in reducing the backflow of fluid into orifices 132. In some embodiments, the height of bottom chamber 150 is the maximum deflection of cooling element 120 plus at least five micrometers and not more than ten micrometers. In some embodiments, the deflection of cooling element 120 (e.g. the deflection of tip 121), z, has an amplitude of at least ten micrometers and not more than one hundred micrometers. In some such embodiments, the amplitude of deflection of cooling element 120 is at least ten micrometers and not more than sixty micrometers. However, the amplitude of deflection of cooling element 120 depends on factors such as the desired flow rate through cooling system 100 and the configuration of cooling system 100. Thus, the height of bottom chamber 150 generally depends on the flow rate through and other components of cooling system 100.

Top plate 110 includes vent 112 through which fluid may be drawn into cooling system 100. Top vent 112 may have a size chosen based on the desired acoustic pressure in chamber 140. For example, in some embodiments, the width, w, of vent 112 is at least five hundred micrometers and not more than one thousand micrometers. In some embodiments, the width of vent 112 is at least two hundred fifty micrometers and not more than two thousand micrometers. In the embodiment shown, vent 112 is a centrally located aperture in top plate 110. In other embodiments, vent 112 may be located elsewhere. For example, vent 112 may be closer to one of the edges of top plate 110. Vent 112 may have a circular, rectangular or other shaped footprint. Although a single vent 112 is shown, multiple vents might be used. For example, vents may be offset toward the edges of top chamber 140 or be located on the side(s) of top chamber 140. Although top plate 110 is shown as substantially flat, in some embodiments trenches and/or other structures may be provided in top plate 110 to modify the configuration of top chamber 140 and/or the region above top plate 110.

Anchor (support structure) 160 supports cooling element 120 at the central portion of cooling element 120. Thus, at least part of the perimeter of cooling element 120 is unpinned and free to vibrate. In some embodiments, anchor 160 extends along a central axis of cooling element 120 (e.g. perpendicular to the page in FIGS. 1A-1F). In such embodiments, portions of cooling element 120 that vibrate (e.g. including tip 121) move in a cantilevered fashion. Thus, portions of cooling element 120 may move in a manner analogous to the wings of a butterfly (i.e. in phase) and/or analogous to a seesaw (i.e. out of phase). Thus, the portions of cooling element 120 that vibrate in a cantilevered fashion do so in phase in some embodiments and out of phase in other embodiments. In some embodiments, anchor 160 does not extend along an axis of cooling element 120. In such embodiments, all portions of the perimeter of cooling element 120 are free to vibrate (e.g. analogous to a jellyfish). In the embodiment shown, anchor 160 supports cooling element 120 from the bottom of cooling element 120. In other embodiments, anchor 160 may support cooling element 120 in another manner. For example, anchor 160 may support cooling element 120 from the top (e.g. cooling element 120 hangs from anchor 160). In some embodiments, the width, a, of anchor 160 is at least 0.5 millimeters and not more than four millimeters. In some embodiments, the width of anchor 160 is at least two millimeters and not more than 2.5 millimeters. Anchor 160 may occupy at least ten percent and not more than fifty percent of cooling element 120.

Cooling element 120 has a first side distal from heat-generating structure 102 and a second side proximate to heat-generating structure 102. In the embodiment shown in FIGS. 1A-1F, the first side of cooling element 120 is the top of cooling element 120 (closer to top plate 110) and the second side is the bottom of cooling element 120 (closer to orifice plate 130). Cooling element 120 is actuated to undergo vibrational motion as shown in FIGS. 1A-1F. The vibrational motion of cooling element 120 drives fluid from the first side of cooling element 120 distal from heat-generating structure 102 (e.g. from top chamber 140) to a second side of cooling element 120 proximate to heat-generating structure 102 (e.g. to bottom chamber 150). The vibrational motion of cooling element 120 also draws fluid through vent 112 and into top chamber 140; forces fluid from top chamber 140 to bottom chamber 150; and drives fluid from bottom chamber 150 through orifices 132 of orifice plate 130. Thus, cooling element 120 may be viewed as an actuator. Although described in the context of a single, continuous cooling element, in some embodiments, cooling element 120 may be formed by two (or more) cooling elements. Each of the cooling elements is depicted as one portion pinned (e.g. supported by support structure 160) and an opposite portion unpinned. Thus, a single, centrally supported cooling element 120 may be formed by a combination of multiple cooling elements supported at an edge.

Cooling element 120 has a length, L, that depends upon the frequency at which cooling element 120 is desired to vibrate. In some embodiments, the length of cooling element 120 is at least four millimeters and not more than ten millimeters. In some such embodiments, cooling element 120 has a length of at least six millimeters and not more than eight millimeters. The depth of cooling element 120 (e.g. perpendicular to the plane shown in FIGS. 1A-1F) may vary from one fourth of L through twice L. For example, cooling element 120 may have the same depth as length. The thickness, t, of cooling element 120 may vary based upon the configuration of cooling element 120 and/or the frequency at which cooling element 120 is desired to be actuated. In some embodiments, the cooling element thickness is at least two hundred micrometers and not more than three hundred and fifty micrometers for cooling element 120 having a length of eight millimeters and driven at a frequency of at least twenty kilohertz and not more than twenty-five kilohertz. The length, C, of chamber 140/150 is close to the length, L, of cooling element 120. For example, in some embodiments, the distance, d, between the edge of cooling element 120 and the wall of chamber 140/150 is at least one hundred micrometers and not more than five hundred micrometers. In some embodiments, d is at least two hundred micrometers and not more than three hundred micrometers.

Cooling element 120 may be driven at a frequency that is at or near both the resonant frequency for an acoustic resonance of a pressure wave of the fluid in top chamber 140 and the resonant frequency for a structural resonance of cooling element 120. The portion of cooling element 120 undergoing vibrational motion is driven at or near resonance (the “structural resonance”) of cooling element 120. This portion of cooling element 120 undergoing vibration may be a cantilevered section in some embodiments. The frequency of vibration for structural resonance is termed the structural resonant frequency. Use of the structural resonant frequency in driving cooling element 120 reduces the power consumption of cooling system 100. Cooling element 120 and top chamber 140 may also be configured such that this structural resonant frequency corresponds to a resonance in a pressure wave in the fluid being driven through top chamber 140 (the acoustic resonance of top chamber 140). The frequency of such a pressure wave is termed the acoustic resonant frequency. At acoustic resonance, a node in pressure occurs near vent 112 and an antinode in pressure occurs near the periphery of cooling system 100 (e.g. near tip 121 of cooling element 120 and near the connection between top chamber 140 and bottom chamber 150). The distance between these two regions is C/2. Thus, C/2=nλ/4, where λ is the acoustic wavelength for the fluid and n is odd (e.g. n=1, 3, 5, etc.). For the lowest order mode, C=λ/2. Because the length of chamber 140 (e.g. C) is close to the length of cooling element 120, in some embodiments, it is also approximately true that L/2=nλ/4, where λ is the acoustic wavelength for the fluid and n is odd. Thus, the frequency at which cooling element 120 is driven, v, is at or near the structural resonant frequency for cooling element 120. The frequency v is also at or near the acoustic resonant frequency for at least top chamber 140. The acoustic resonant frequency of top chamber 140 generally varies less dramatically with parameters such as temperature and size than the structural resonant frequency of cooling element 120. Consequently, in some embodiments, cooling element 120 may be driven at (or closer to) a structural resonant frequency rather than to the acoustic resonant frequency.

Orifice plate 130 has orifices 132 and cavities 134 therein. Although a particular number and distribution of orifices 132 and cavities 134 are shown, another number and/or another distribution may be used. Cavities 134 may be configured differently or may be omitted. In some embodiments, other cavities may be within flow chamber 140/150 or the jet channel between orifice plate 130 and heat-generating structure 102. For example, cavities may be included in top plate 110 within flow chamber 140/150 or in the bottom of orifice plate 130. A single orifice plate 130 is used for a single cooling system 100. In other embodiments, multiple cooling systems 100 may share an orifice plate. For example, multiple cells 100 may be provided together in a desired configuration. In such embodiments, the cells 100 may be the same size and configuration or different size(s) and/or configuration(s). Orifices 132 are shown as having an axis oriented normal to a surface of heat-generating structure 102. In other embodiments, the axis of one or more orifices 132 may be at another angle. For example, the angle of the axis may be selected from substantially zero degrees and a nonzero acute angle. Orifices 132 also have sidewalls that are substantially parallel to the normal to the surface of orifice plate 130. In some embodiments, orifices may have sidewalls at a nonzero angle to the normal to the surface of orifice plate 130. For example, orifices 132 may be cone-shaped. Further, although orifice place 130 is shown as substantially flat, in some embodiments, trenches and/or other structures may be provided in orifice plate 130 to modify the configuration of bottom chamber 150 and/or the region between orifice plate 130 and heat-generating structure 102.

The size, distribution and locations of orifices 132 are chosen to control the flow rate of fluid driven to the surface of heat-generating structure 102. The locations and configurations of orifices 132 may be configured to increase/maximize the fluid flow from bottom chamber 150 through orifices 132 to the jet channel (the region between the bottom of orifice plate 130 and the top of heat-generating structure 102). The locations and configurations of orifices 132 may also be selected to reduce/minimize the suction flow (e.g. back flow) from the jet channel through orifices 132. For example, the locations of orifices are desired to be sufficiently far from tip 121 that suction in the upstroke of cooling element 120 (tip 121 moves away from orifice plate 130) that would pull fluid into bottom chamber 150 through orifices 132 is reduced. The locations of orifices are also desired to be sufficiently close to tip 121 that suction in the upstroke of cooling element 120 also allows a higher pressure from top chamber 140 to push fluid from top chamber 140 into bottom chamber 150. In some embodiments, the ratio of the flow rate from top chamber 140 into bottom chamber 150 to the flow rate from the jet channel through orifices 132 in the upstroke (the “net flow ratio”) is greater than 2:1. In some embodiments, the net flow ratio is at least 85:15. In some embodiments, the net flow ratio is at least 90:10. In order to provide the desired pressure, flow rate, suction, and net flow ratio, orifices 132 are desired to be at least a distance, r1, from tip 121 and not more than a distance, r2, from tip 121 of cooling element 120. In some embodiments, r1 is at least one hundred micrometers (e.g. r1≥100 μm) and r2 is not more than one millimeter (e.g. r2≤1000 μm). In some embodiments, orifices 132 are at least two hundred micrometers from tip 121 of cooling element 120 (e.g. r1≥200 μm). In some such embodiments, orifices 132 are at least three hundred micrometers from tip 121 of cooling element 120 (e.g. r1≥300 μm). In some embodiments, orifices 132 have a width, o, of at least one hundred micrometers and not more than five hundred micrometers. In some embodiments, orifices 132 have a width of at least two hundred micrometers and not more than three hundred micrometers. In some embodiments, the orifice separation, s, is at least one hundred micrometers and not more than one millimeter. In some such embodiments, the orifice separation is at least four hundred micrometers and not more than six hundred micrometers. In some embodiments, orifices 132 are also desired to occupy a particular fraction of the area of orifice plate 130. For example, orifices 132 may cover at least five percent and not more than fifteen percent of the footprint of orifice plate 130 in order to achieve a desired flow rate of fluid through orifices 132. In some embodiments, orifices 132 cover at least eight percent and not more than twelve percent of the footprint of orifice plate 130.

In some embodiments, cooling element 120 is actuated using a piezoelectric. Thus, cooling element 120 may be a piezoelectric cooling element. Cooling element 120 may be driven by a piezoelectric that is mounted on or integrated into cooling element 120. In some embodiments, cooling element 120 is driven in another manner including but not limited to providing a piezoelectric on another structure in cooling system 100. Cooling element 120 and analogous cooling elements are referred to hereinafter as piezoelectric cooling elements though it is possible that a mechanism other than a piezoelectric might be used to drive the cooling element. In some embodiments, cooling element 120 includes a piezoelectric layer on substrate. The substrate may include or consist of stainless steel, a Ni alloy, Hastelloy, Al (e.g. an Al alloy), and/or Ti (e.g. a Ti alloy such as Ti6Al-4V). In some embodiments, a piezoelectric layer includes multiple sublayers formed as thin films on the substrate. In other embodiments, the piezoelectric layer may be a bulk layer affixed to the substrate. Such a piezoelectric cooling element 120 also includes electrodes used to activate the piezoelectric. The substrate functions as an electrode in some embodiments. In other embodiments, a bottom electrode may be provided between the substrate and the piezoelectric layer. Other layers including but not limited to seed, capping, passivation, or other layers might be included in the piezoelectric cooling element. Thus, cooling element 120 may be actuated using a piezoelectric.

In some embodiments, cooling system 100 includes chimneys (not shown) or other ducting. Such ducting provides a path for heated fluid to flow away from heat-generating structure 102. In some embodiments, ducting returns fluid to the side of top plate 110 distal from heat-generating structure 102. In some embodiments, ducting may instead direct fluid away from heat-generating structure 102 in a direction parallel to heat-generating structure 102 or perpendicular to heat-generating structure 102 but in the opposite direction (e.g. toward the bottom of the page). For a device in which fluid external to the device is used in cooling system 100, the ducting may channel the heated fluid to a vent. In such embodiments, additional fluid may be provided from an inlet vent. In embodiments, in which the device is enclosed, the ducting may provide a circuitous path back to the region near vent 112 and distal from heat-generating structure 102. Such a path allows for the fluid to dissipate heat before being reused to cool heat-generating structure 102. In other embodiments, ducting may be omitted or configured in another manner. Thus, the fluid is allowed to carry away heat from heat-generating structure 102.

Operation of cooling system 100 is described in the context of FIGS. 1A-1F. Although described in the context of particular pressures, gap sizes, and timing of flow, operation of cooling system 100 is not dependent upon the explanation herein. FIGS. 1C-1D depict in-phase operation of cooling system 100. Referring to FIG. 1C, cooling element 120 has been actuated so that its tip 121 moves away from top plate 110. FIG. 1C can thus be considered to depict the end of a down stroke of cooling element 120. Because of the vibrational motion of cooling element 120, gap 152 for bottom chamber 150 has decreased in size and is shown as gap 152B. Conversely, gap 142 for top chamber 140 has increased in size and is shown as gap 142B. During the down stroke, a lower (e.g. minimum) pressure is developed at the periphery when cooling element 120 is at the neutral position. As the down stroke continues, bottom chamber 150 decreases in size and top chamber 140 increases in size as shown in FIG. 1C. Thus, fluid is driven out of orifices 132 in a direction that is at or near perpendicular to the surface of orifice plate 130 and/or the top surface of heat-generating structure 102. The fluid is driven from orifices 132 toward heat-generating structure 102 at a high speed, for example in excess of thirty-five meters per second. In some embodiments, the fluid then travels along the surface of heat-generating structure 102 and toward the periphery of heat-generating structure 102, where the pressure is lower than near orifices 132. Also in the down stroke, top chamber 140 increases in size and a lower pressure is present in top chamber 140. As a result, fluid is drawn into top chamber 140 through vent 112. The motion of the fluid into vent 112, through orifices 132, and along the surface of heat-generating structure 102 is shown by unlabeled arrows in FIG. 1C.

Cooling element 120 is also actuated so that tip 121 moves away from heat-generating structure 102 and toward top plate 110. FIG. 1D can thus be considered to depict the end of an up stroke of cooling element 120. Because of the motion of cooling element 120, gap 142 has decreased in size and is shown as gap 142C. Gap 152 has increased in size and is shown as gap 152C. During the upstroke, a higher (e.g. maximum) pressure is developed at the periphery when cooling element 120 is at the neutral position. As the upstroke continues, bottom chamber 150 increases in size and top chamber 140 decreases in size as shown in FIG. 1D. Thus, the fluid is driven from top chamber 140 (e.g. the periphery of chamber 140/150) to bottom chamber 150. Thus, when tip 121 of cooling element 120 moves up, top chamber 140 serves as a nozzle for the entering fluid to speed up and be driven towards bottom chamber 150. The motion of the fluid into bottom chamber 150 is shown by unlabeled arrows in FIG. 1D. The location and configuration of cooling element 120 and orifices 132 are selected to reduce suction and, therefore, back flow of fluid from the jet channel (between heat-generating structure 102 and orifice plate 130) into orifices 132 during the upstroke. Thus, cooling system 100 is able to drive fluid from top chamber 140 to bottom chamber 150 without an undue amount of backflow of heated fluid from the jet channel entering bottom chamber 150. Moreover, cooling system 100 may operate such that fluid is drawn in through vent 112 and driven out through orifices 132 without cooling element 120 contacting top plate 110 or orifice plate 130. Thus, pressures are developed within chambers 140 and 150 that effectively open and close vent 112 and orifices 132 such that fluid is driven through cooling system 100 as described herein.

The motion between the positions shown in FIGS. 1C and 1D is repeated. Thus, cooling element 120 undergoes vibrational motion indicated in FIGS. 1A-1D, drawing fluid through vent 112 from the distal side of top plate 110 into top chamber 140; transferring fluid from top chamber 140 to bottom chamber 150; and pushing the fluid through orifices 132 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at frequencies from 15 kHz through 30 kHz. In some embodiments, cooling element 120 vibrates at a frequency/frequencies of at least 20 kHz and not more than 30 kHz. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 may move substantially normal (perpendicular) to the top surface of heat-generating structure 102. In some embodiments, the fluid motion may have a nonzero acute angle with respect to the normal to the top surface of heat-generating structure 102. In either case, the fluid may thin and/or form apertures in the boundary layer of fluid at heat-generating structure 102. As a result, transfer of heat from heat-generating structure 102 may be improved. The fluid deflects off of heat-generating structure 102, traveling along the surface of heat-generating structure 102. In some embodiments, the fluid moves in a direction substantially parallel to the top of heat-generating structure 102. Thus, heat from heat-generating structure 102 may be extracted by the fluid. The fluid may exit the region between orifice plate 130 and heat-generating structure 102 at the edges of cooling system 100. Chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

FIGS. 1E-1F depict an embodiment of active MEMS cooling system 100 including centrally anchored cooling element 120 in which the cooling element is driven out-of-phase. More specifically, sections of cooling element 120 on opposite sides of anchor 160 (and thus on opposite sides of the central region of cooling element 120 that is supported by anchor 160) are driven to vibrate out-of-phase. In some embodiments, sections of cooling element 120 on opposite sides of anchor 160 are driven at or near one hundred and eighty degrees out-of-phase. Thus, one section of cooling element 120 vibrates toward top plate 110, while the other section of cooling element 120 vibrates toward orifice plate 130/heat-generating structure 102. Movement of a section of cooling element 120 toward top plate 110 (an upstroke) drives fluid in top chamber 140 to bottom chamber 150 on that side of anchor 160. Movement of a section of cooling element 120 toward orifice plate 130 drives fluid through orifices 132 and toward heat-generating structure 102. Thus, fluid traveling at high speeds (e.g. speeds described with respect to in-phase operation) is alternately driven out of orifices 132 on opposing sides of anchor 160. Because fluid is driven through orifices 132 at high speeds, cooling system 100 may be viewed as a MEMs jet. The movement of fluid is shown by unlabeled arrows in FIGS. 1E and 1F. The motion between the positions shown in FIGS. 1E and 1F is repeated. Thus, cooling element 120 undergoes vibrational motion indicated in FIGS. 1A, 1E, and 1F, alternately drawing fluid through vent 112 from the distal side of top plate 110 into top chamber 140 for each side of cooling element 120; transferring fluid from each side of top chamber 140 to the corresponding side of bottom chamber 150; and pushing the fluid through orifices 132 on each side of anchor 160 and toward heat-generating structure 102. As discussed above, cooling element 120 is driven to vibrate at or near the structural resonant frequency of cooling element 120. Further, the structural resonant frequency of cooling element 120 is configured to align with the acoustic resonance of the chamber 140/150. The structural and acoustic resonant frequencies are generally chosen to be in the ultrasonic range. For example, the vibrational motion of cooling element 120 may be at the frequencies described for in-phase vibration. The structural resonant frequency of cooling element 120 is within ten percent of the acoustic resonant frequency of cooling system 100. In some embodiments, the structural resonant frequency of cooling element 120 is within five percent of the acoustic resonant frequency of cooling system 100. In some embodiments, the structural resonant frequency of cooling element 120 is within three percent of the acoustic resonant frequency of cooling system 100. Consequently, efficiency and flow rate may be enhanced. However, other frequencies may be used.

Fluid driven toward heat-generating structure 102 for out-of-phase vibration may move substantially normal (perpendicular) to the top surface of heat-generating structure 102, in a manner analogous to that described above for in-phase operation. Similarly, chimneys or other ducting (not shown) at the edges of cooling system 100 allow fluid to be carried away from heat-generating structure 102. In other embodiments, heated fluid may be transferred further from heat-generating structure 102 in another manner. The fluid may exchange the heat transferred from heat-generating structure 102 to another structure or to the ambient environment. Thus, fluid at the distal side of top plate 110 may remain relatively cool, allowing for the additional extraction of heat. In some embodiments, fluid is circulated, returning to the distal side of top plate 110 after cooling. In other embodiments, heated fluid is carried away and replaced by new fluid at the distal side of cooling element 120. As a result, heat-generating structure 102 may be cooled.

Although shown in the context of a uniform cooling element in FIGS. 1A-1F, cooling system 100 may utilize cooling elements having different shapes. FIG. 1G depicts an embodiment of engineered cooling element 120′ having a tailored geometry and usable in a cooling system such as cooling system 100. Cooling element 120′ includes an anchored region 122 and cantilevered arms 123. Anchored region 122 is supported (e.g. held in place) in cooling system 100 by anchor 160. Cantilevered arms 123 undergo vibrational motion in response to cooling element 120′ being actuated. Each cantilevered arm 123 includes step region 124, extension region 126 and outer region 128. In the embodiment shown in FIG. 1G, anchored region 122 is centrally located. Step region 124 extends outward from anchored region 122. Extension region 126 extends outward from step region 124. Outer region 128 extends outward from extension region 126. In other embodiments, anchored region 122 may be at one edge of the actuator and outer region 128 at the opposing edge. In such embodiments, the actuator is edge anchored.

Extension region 126 has a thickness (extension thickness) that is less than the thickness of step region 124 (step thickness) and less than the thickness of outer region 128 (outer thickness). Thus, extension region 126 may be viewed as recessed. Extension region 126 may also be seen as providing a larger bottom chamber 150. In some embodiments, the outer thickness of outer region 128 is the same as the step thickness of step region 124. In some embodiments, the outer thickness of outer region 128 is different from the step thickness of step region 124. In some embodiments, outer region 128 and step region 124 each have a thickness of at least three hundred twenty micrometers and not more than three hundred and sixty micrometers. In some embodiments, the outer thickness is at least fifty micrometers and not more than two hundred micrometers thicker than the extension thickness. Stated differently, the step (difference in step thickness and extension thickness) is at least fifty micrometers and not more than two hundred micrometers. In some embodiments, the outer step (difference in outer thickness and extension thickness) is at least fifty micrometers and not more than two hundred micrometers. Outer region 128 may have a width, o, of at least one hundred micrometers and not more than three hundred micrometers. Extension region 126 has a length, e, extending outward from the step region of at least 0.5 millimeter and not more than 1.5 millimeters in some embodiments. In some embodiments, outer region 128 has a higher mass per unit length in the direction from anchored region 122 than extension region 126. This difference in mass may be due to the larger size of outer region 128, a difference in density between portions of cooling element 120, and/or another mechanism.

Use of engineered cooling element 120′ may further improve efficiency of cooling system 100. Extension region 126 is thinner than step region 124 and outer region 128. This results in a cavity in the bottom of cooling element 120′ corresponding to extension region 126. The presence of this cavity aids in improving the efficiency of cooling system 100. Each cantilevered arm 123 vibrates towards top plate 110 in an upstroke and away from top plate 110 in a downstroke. When a cantilevered arm 123 moves toward top plate 110, higher pressure fluid in top chamber 140 resists the motion of cantilevered arm 123. Furthermore, suction in bottom chamber 150 also resists the upward motion of cantilevered arm 123 during the upstroke. In the downstroke of cantilevered arm 123, increased pressure in the bottom chamber 150 and suction in top chamber 140 resist the downward motion of cantilevered arm 123. However, the presence of the cavity in cantilevered arm 123 corresponding to extension region 126 mitigates the suction in bottom chamber 150 during an upstroke. The cavity also reduces the increase in pressure in bottom chamber 150 during a downstroke. Because the suction and pressure increase are reduced in magnitude, cantilevered arms 123 may more readily move through the fluid. This may be achieved while substantially maintaining a higher pressure in top chamber 140, which drives the fluid flow through cooling system 100. Moreover, the presence of outer region 128 may improve the ability of cantilevered arm 123 to move through the fluid being driven through cooling system 100. Outer region 128 has a higher mass per unit length and thus a higher momentum. Consequently, outer region 128 may improve the ability of cantilevered arms 123 to move through the fluid being driven through cooling system 100. The magnitude of the deflection of cantilevered arm 123 may also be increased. These benefits may be achieved while maintaining the stiffness of cantilevered arms 123 through the use of thicker step region 124. Further, the larger thickness of outer region 128 may aid in pinching off flow at the bottom of a downstroke. Thus, the ability of cooling element 120′ to provide a valve preventing backflow through orifices 132 may be improved. Thus, performance of cooling system 100 employing cooling element 120′ may be improved.

Further, cooling elements used in cooling system 100 may have different structures and/or be mounted differently than depicted in FIGS. 1A-1G. In some embodiments, the cooling element may have rounded corners and/or rounded ends but still be anchored along a central axis such that cantilevered arms vibrate. The cooling element may be anchored only at its central region such that the regions surrounding the anchor vibrate in a manner analogous to a jellyfish or the opening/closing of an umbrella. In some such embodiments, the cooling element may be circular or elliptical in shape. In some embodiments, the anchor may include apertures through which fluid may flow. Such an anchor may be utilized for the cooling element being anchored at its top (e.g. to the top plate). Although not indicated in FIGS. 1A-1G, the piezoelectric utilized in driving the cooling element may have various locations and/or configurations. For example, the piezoelectric may be embedded in the cooling element, affixed to one side of the cooling element (or cantilevered arm(s)), may occupy some or all of the cantilevered arms, and/or may have a location that is close to or distal from the anchored region. In some embodiments, cooling elements that are not centrally anchored may be used. For example, a pair of cooling elements that have offset apertures, that are anchored at their ends (or all edges), and which vibrate out of phase may be used. Thus, various additional configurations of cooling element 120 and/or 120′, anchor 160, and/or other portions of cooling system 100 may be used.

Using the cooling system 100 actuated for in-phase vibration or out-of-phase vibration of cooling element 120 and/or 120′, fluid drawn in through vent 112 and driven through orifices 132 may efficiently dissipate heat from heat-generating structure 102. Because fluid impinges upon the heat-generating structure with sufficient speed (e.g. at least thirty meters per second) and in some embodiments substantially normal to the heat-generating structure, the boundary layer of fluid at the heat-generating structure may be thinned and/or partially removed. Consequently, heat transfer between heat-generating structure 102 and the moving fluid is improved. Because the heat-generating structure is more efficiently cooled, the corresponding integrated circuit may be run at higher speed and/or power for longer times. For example, if the heat-generating structure corresponds to a high-speed processor, such a processor may be run for longer times before throttling. Thus, performance of a device utilizing cooling system 100 may be improved. Further, cooling system 100 may be a MEMS device. Consequently, cooling systems 100 may be suitable for use in smaller and/or mobile devices, such as smart phones, other mobile phones, virtual reality headsets, tablets, two-in-one computers, wearables and handheld games, in which limited space is available. Performance of such devices may thus be improved. Because cooling element 120/120′ may be vibrated at frequencies of 15 kHz or more, users may not hear any noise associated with actuation of cooling elements. If driven at or near structural and/or acoustic resonant frequencies, the power used in operating cooling systems may be significantly reduced. Cooling element 120/120′ does not physically contact top plate 110 or orifice plate 130 during vibration. Thus, resonance of cooling element 120/120′ may be more readily maintained. More specifically, physical contact between cooling element 120/120′ and other structures disturbs the resonance conditions for cooling element 120/120′. Disturbing these conditions may drive cooling element 120/120′ out of resonance. Thus, additional power would need to be used to maintain actuation of cooling element 120/120′. Further, the flow of fluid driven by cooling element 120/120′ may decrease. These issues are avoided through the use of pressure differentials and fluid flow as discussed above. The benefits of improved, quiet cooling may be achieved with limited additional power. Further, out-of-phase vibration of cooling element 120/120′ allows the position of the center of mass of cooling element 120/120′ to remain more stable. Although a torque is exerted on cooling element 120/120′, the force due to the motion of the center of mass is reduced or eliminated. As a result, vibrations due to the motion of cooling element 120/120′ may be reduced. Moreover, efficiency of cooling system 100 may be improved through the use of out-of-phase vibrational motion for the two sides of cooling element 120/120′. Consequently, performance of devices incorporating the cooling system 100 may be improved. Further, cooling system 100 may be usable in other applications (e.g. with or without heat-generating structure 102) in which high fluid flows and/or velocities are desired.

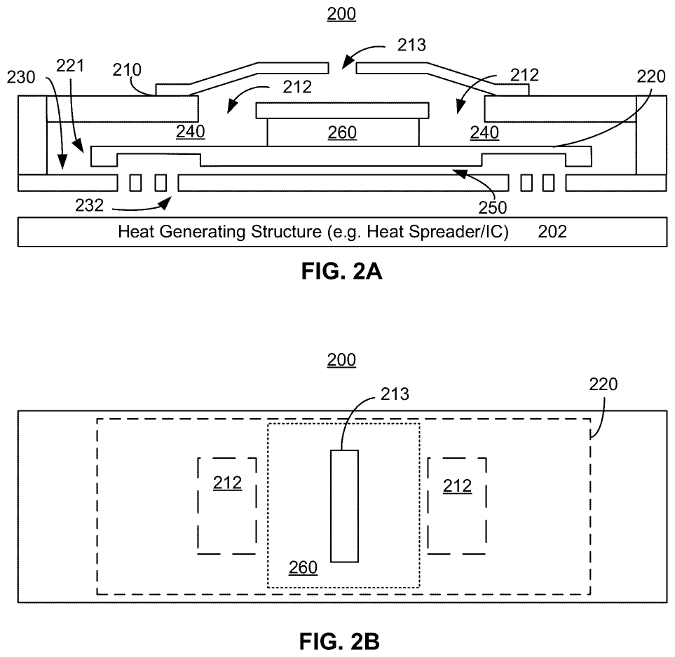

FIGS. 2A-2B depict an embodiment of active MEMS cooling system 200 including a top centrally anchored cooling element. FIG. 2A depicts a side view of cooling system 200 in a neutral position. FIG. 2B depicts a top view of cooling system 200. FIGS. 2A-2B are not to scale. For simplicity, only portions of cooling system 200 are shown. Referring to FIGS. 2A-2B, cooling system 200 is analogous to cooling system 100. Consequently, analogous components have similar labels. For example, cooling system 200 is used in conjunction with heat-generating structure 202, which is analogous to heat-generating structure 102.

Cooling system 200 includes top plate 210 having vents 212, cooling element 220 having tip 221, orifice plate 230 including orifices 232, top chamber 240 having a gap, bottom chamber 250 having a gap, flow chamber 240/250, and anchor (i.e. support structure) 260 that are analogous to top plate 110 having vent 112, cooling element 120 having tip 121, orifice plate 130 including orifices 132, top chamber 140 having gap 142, bottom chamber 150 having gap 152, flow chamber 140/150, and anchor (i.e. support structure) 160, respectively. Also shown is pedestal 290 that is analogous to pedestal 190. Thus, cooling element 220 is centrally supported by anchor 260 such that at least a portion of the perimeter of cooling element 220 is free to vibrate. In some embodiments, anchor 260 extends along the axis of cooling element 220. In other embodiments, anchor 260 is only near the center portion of cooling element 220. Although not explicitly labeled in FIGS. 2A and 2B, cooling element 220 includes an anchored region and cantilevered arms including step region, extension region, and outer regions analogous to anchored region 122, cantilevered arms 123, step region 124, extension region 126, and outer region 128 of cooling element 120′. In some embodiments, cantilevered arms of cooling element 220 are driven in-phase. In some embodiments, cantilevered arms of cooling element 220 are driven out-of-phase. In some embodiments, a simple cooling element, such as cooling element 120, may be used.

Anchor 260 supports cooling element 220 from above. Thus, cooling element 220 is suspended from anchor 260. Anchor 260 is suspended from top plate 210. Top plate 210 includes vent 213. Vents 212 on the sides of anchor 260 provide a path for fluid to flow into sides of chamber 240.

As discussed above with respect to cooling system 100, cooling element 220 may be driven to vibrate at or near the structural resonant frequency of cooling element 220. Further, the structural resonant frequency of cooling element 220 may be configured to align with the acoustic resonance of chamber 240/250. The structural and acoustic resonant frequencies are generally chosen to be in the ultrasonic range. For example, the vibrational motion of cooling element 220 may be at the frequencies described with respect to cooling system 100. Consequently, efficiency and flow rate may be enhanced. However, other frequencies may be used.

Cooling system 200 operates in an analogous manner to cooling system 100. Cooling system 200 thus shares the benefits of cooling system 100. Thus, performance of a device employing cooling system 200 may be improved. In addition, suspending cooling element 220 from anchor 260 may further enhance performance. In particular, vibrations in cooling system 200 that may affect other cooling cells (not shown) may be reduced. For example, less vibration may be induced in top plate 210 due to the motion of cooling element 220. Consequently, cross talk between cooling system 200 and other cooling systems (e.g. other cells) or other portions of the device incorporating cooling system 200 may be reduced. Thus, performance may be further enhanced.

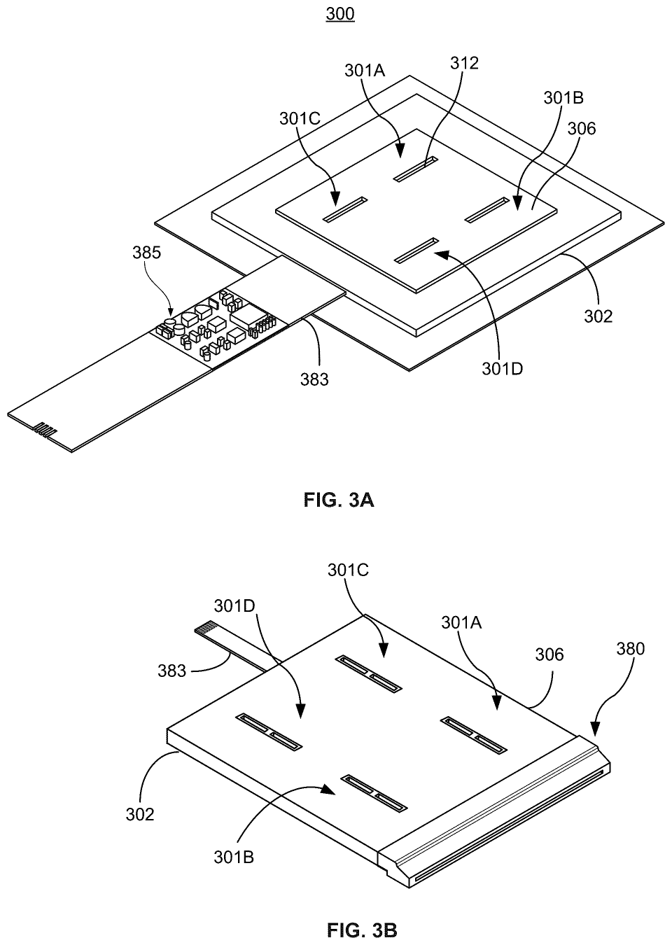

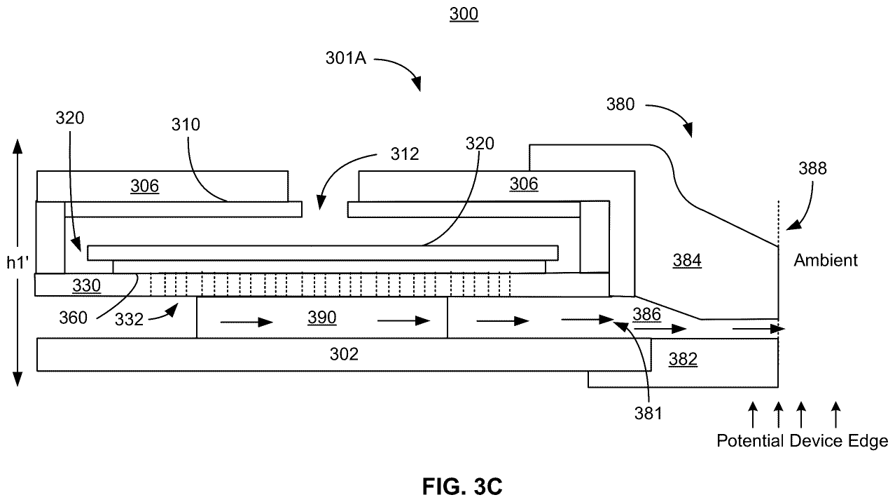

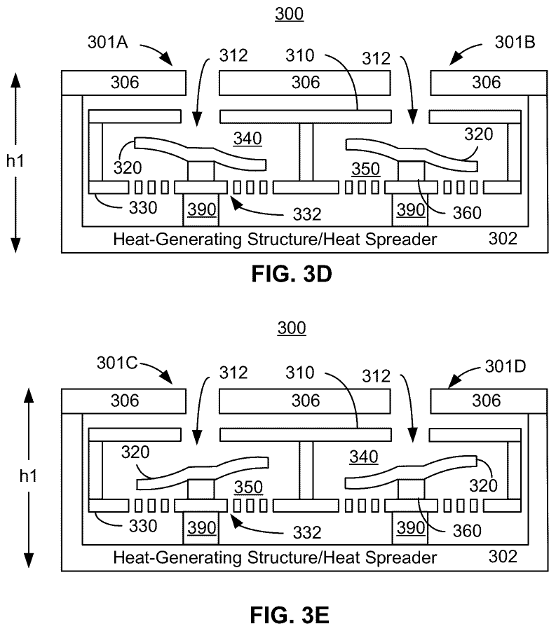

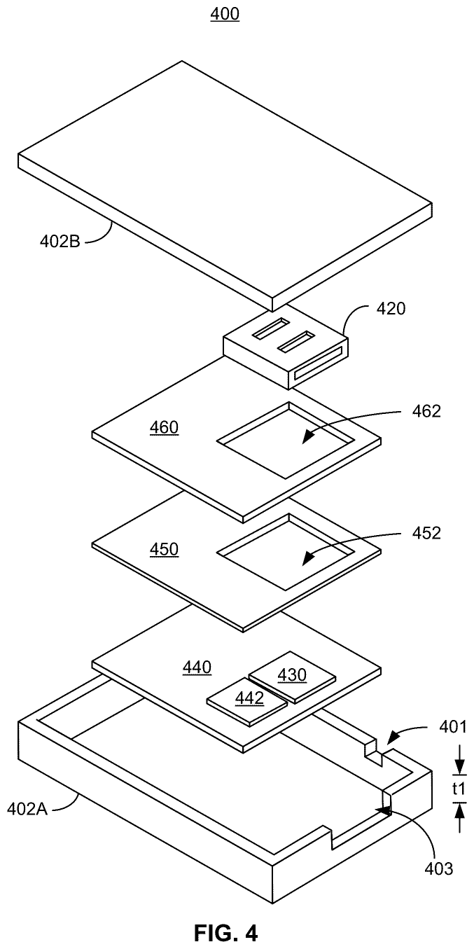

FIGS. 3A-3E depict an embodiment of active MEMS cooling system 300 including multiple cooling cells configured as a module termed a tile, or array. FIG. 3A depicts a perspective view with cover 306 and spout 380 removed. FIG. 3B depicts active MEMS cooling system 300 with cover 306 and spout 380. FIG. 3C depicts a side view of a portion of cooling system 300. FIGS. 3D-3E depict side views of cooling system 300. FIGS. 3A-3E are not to scale. Cooling system 300 includes four cooling cells 301A, 301B, 301C and 301D (collectively or generically 301), which are analogous to one or more of cooling systems described herein. More specifically, cooling cells 301 are analogous to cooling system 100 and/or 200. Tile 300 thus includes four cooling cells 301 (i.e. four MEMS jets). Although four cooling cells 301 in a 2×2 configuration are shown, in some embodiments another number and/or another configuration of cooling cells 301 might be employed. In the embodiment shown, cooling cells 301 include shared top plate 310 having apertures 312, cooling elements 320, shared orifice plate 330 including orifices 332, top chambers 340, bottom chambers 350, anchors (support structures) 360, and pedestals 390 that are analogous to top plate 110 having apertures 112, cooling element 120, orifice plate 130 having orifices 132, top chamber 140, bottom chamber 150, anchor 160, and pedestal 190. In some embodiments, cooling cells 301 may be fabricated together and separated, for example by cutting through top plate 310, side walls between cooling cells 301, and orifice plate 330. Thus, although described in the context of a shared top plate 310 and shared orifice plate 330, after fabrication cooling cells 301 may be separated. In some embodiments, tabs (not shown) and/or other structures such as anchors 360 may connect cooling cells 301. Further, tile 300 includes heat-generating structure (termed a heat spreader hereinafter) 302 (e.g. a heat spreader, a heat spreader, and/or other structure) that also has sidewalls, or fencing, in the embodiment shown. Cover 306 having apertures therein is also shown. In some embodiments, a dust filter (not shown) may be provided for the apertures. In such embodiments, dust may be less likely to reach the interior of cooling system 300. In some embodiments, a water tight, air porous membrane may be provided for the apertures. Heat spreader 302, cover 306, and spout 380 may be part of an integrated tile 300 as shown or may be separate from tile 300 in other embodiments. Heat spreader 302 and cover plate 306 may direct fluid flow outside of cooling cells 301, provide mechanical stability, and/or provide protection. Electrical connection to cooling cells 301 is provided via flex connector 383 (not shown in FIGS. 3C-3E) which may house drive electronics 385. The total height of cooling system 300, h1′, does not exceed 3.5 millimeters. In some such embodiments, h1′ is not more than three millimeters. In some embodiments, h1′ is not more than 2.5 millimeters. In some embodiments, h1′ is at least two millimeters. For example, h1′ may be at least 2.7 millimeters and not more than 3.2 millimeters. Cooling elements 320 are driven out-of-phase (i.e. in a manner analogous to a seesaw). Further, as can be seen in FIGS. FIGS. 3D-3E cooling element 320 in one cell is driven out-of-phase with cooling element(s) 320 in adjacent cell(s). Cooling element 320 in cell 301C is out-of-phase with cooling element 320 in cell 301D. In FIGS. 3D-3E, cooling elements 320 in a column are driven out-of-phase. Thus, cooling element 320 in cell 301A is out-of-phase with cooling element 320 in cell 301C. Similarly, cooling element 320 in cell 301B is out-of-phase with cooling element 320 in cell 301D. By driving cooling elements 320 out-of-phase, vibrations in cooling system 300 may be reduced. Cooling elements 320 may be driven in another manner in some embodiments.

Cooling system 300 also includes spout 380 having dissipation region 386 therein. Spout 380 includes a housing having bottom 382 and top 384, entrance 381 and exit 386. Entrance 381 is fluidically coupled with orifices 332 (i.e. egresses from flow chamber 340/450). The direction of fluid flow from flow chamber 340/450 may be seen by the unlabeled arrows in FIG. 3C. Spout 380 operates to smooth pulsations in the pressure waves generated by cooling elements 320. Because cooling elements 320 vibrate, the flow of fluid pulsates. Thus, the pressure of the fluid also pulsates between higher and lower pressures. Flow may also exit orifices 332 and travel through the jet channel in pulses. The pressure within flow chamber 340/350 and the jet channel is higher than the pressure of the ambient region. The fluid exits the jet channel and enters spout 380 at entrance 381. The fluid travels through dissipation region 386 and to exit 388. The pulsating pressure in the fluid is dissipated in dissipation region 384. Stated differently, the pulsating pressure way may be attenuated such that the pressure equilibrates and approaches (or reaches) the ambient pressure of the ambient region outside of system 300. In some embodiments, therefore, the pressure of the fluid at exit 388 of spout 380 matches or substantially the boundary conditions for the pressure of the ambient.

Cooling cells 301 of cooling system 300 function in an analogous manner to cooling system(s) 100, 200, and/or an analogous cooling system. Consequently, the benefits described herein may be shared by cooling system 300. Because cooling elements in nearby cells are driven out-of-phase, vibrations in cooling system 300 may be reduced. Because multiple cooling cells 301 are used, cooling system 300 may enjoy enhanced cooling capabilities. Further, multiples of individual cooling cells 301 and/or cooling system 300 may be combined in various fashions to obtain the desired footprint of cooling cells.

Systems 100, 200, and 300 are generally desired to be integrated into devices, such as computing devices, for which cooling is desired. In addition to space and other constraints, cooling systems such as systems 100, 200, and 300 are desired to maintain a higher rate of fluid flow, efficiently transfer heat from the heat-generating structure, and reduce the amount of heat transferred back into the device from the cooling systems. Thus, additional control of the fluid flow through the cooling system and the devices in which such systems are incorporated is desired.

FIGS. 4-9 depict various embodiments of mobile phones including heat transfer structures that incorporate one or more of active cooling system(s) 100, 200, and/or 300 and/or an analogous device. The mobile phones depicted in FIGS. 4-9 may be smart phones. In some embodiments, other mobile computing devices may be used in lieu of mobile phones. Various features are highlighted in FIGS. 4-9 (as well as FIGS. 1A-3E). Various features may be combined in manners not explicitly shown herein.

FIG. 4 depicts an embodiment of active MEMS cooling system 420 as integrated into mobile phone 400. More specifically, FIG. 4 is an exploded view of mobile phone 400. Mobile phone 400 may include bottom cover 402A and top cover 402B (collectively referred to as cover 402). Because mobile phone 400 is thin, mobile phone 400 has a dimension (i.e. a thickness) that is significantly less than the remaining dimensions. For example, the interior of mobile phone 400 in which heat transfer structure 410 resides may have a height, t1, of not more than five millimeters. In some embodiments, t1 is not more than 3.5 millimeters. In some such embodiments, t1 is not more than three millimeters. In some embodiments, t1 is at least two millimeters. For example, t1 may be at least 3.2 millimeters and not more than 4 millimeters. Other heights are possible. In some embodiments, mobile phone 400, has ingress 401 and egress 403. Although a single ingress 401 and a single egress 403 are shown, other numbers of ingresses and/or egresses may be present and their locations can be adjusted on any or all of the four sides or on the back cover. In some embodiments, ingress 401 and egress 403 are water resistant. For example, an IP68 membrane (not shown) or other mechanism for ensuring that the interior of mobile phone 400 is water resistant may be used.

Mobile phone 400 includes circuit board 440, heat-generating structure(s) 430, additional electrical components 442, and cooling system 420. In some embodiments, mobile phone 400 also includes interposer 450 and additional circuit board 460. Additional and/or other components, such as a camera, speaker(s) and microphone(s) (all not shown), may be present. In some embodiments, one or more of the portions of mobile phone 400 may be omitted. Some or all of the components shown (e.g. cooling system 420, circuit boards 440 and 460, interposer 450, and heat-generating structure 430) are contained within cover 402. Thus, components 420, 430, 440, 450, and 460 may be within the interior of mobile phone 400.

Circuit board 440 includes heat-generating structure 430 and additional component 442. Heat-generating structure 430 may be one or more processors or other integrated circuit(s) mounted on circuit board 440. A heat spreader, heat pipe, heat sink, and/or other analogous structure may be coupled to the processor and considered part of heat-generating structure 430. In some embodiments, heat-generating structure 430 may be a battery or other structure to be cooled. Other integrated circuits, such as dynamic random access memory (DRAM) modules (not shown) or other electrical components (not shown) may be mounted on circuit board(s) 440 and/or 460. Although described in the context of transferring heat from a single heat-generating structure 430, in some embodiments, cooling system 420 transfers heat from multiple heat-generating structures (e.g. multiple processors, a processor and a battery, a processor and other components, and/or other components).

Interposer may be used to couple circuit boards 440 and 460, allowing for circuit boards and integrated circuits to be densely packed within the interior of mobile phone 400. This may allow for additional functionality while maintaining a very low profile. For example, interposer 450 may be at least 0.5 millimeters thick and not more than one millimeter thick. Circuit boards 440 and 460 may be nominally 1.3-1.7 millimeters thick.

Cooling system 420 is analogous to cooling system 100, 200, and/or 300. Consequently, the dimensions, fluid flows, fluid speeds, and other properties described herein may be achieved for cooling system 420. For example, cooling system 420 may have a height that is not more than 3.5 millimeters. In some embodiments, the height of cooling system 420 is not more than 2.5 millimeters. In some embodiments, cooling system 420 has a height of at least one millimeter. Other heights are possible. Further, driving cooling system 420 causes vibrational motion to occur in the cooling elements therein. This vibrational motion causes fluid to be drawn into cooling system 420 and driven out of the exit of cooling system 420 at or near egress 403. The vibrational motion of the cooling elements also causes fluid (e.g. air) from exterior to mobile phone 400 to be drawn into the interior of mobile phone 400 via the ingress 401 and expelled via egress 405. In other embodiments, mobile phone 400 might be sealed such that the fluid driven by cooling system 420 remains within the interior of mobile phone 400.

Interposer 450 and circuit board 460 are also configured to maintain a low profile for mobile phone 400 while allowing thermal connectivity between cooling system 420 and heat-generating structure 430. Interposer 450 includes gap 452. In the embodiment shown, gap 452 is an aperture in interpose 450. Circuit board 460 may also include circuit board gap 462. Circuit board gap 462 is configured as an aperture. Gaps 452 and 462 are configured to fit at least a portion of cooling system 420. Thus, the gaps 452 and 462 may be aligned and at least as large as the portion of cooling system 420 desired to fit with gaps 452 and 462. Although shown as substantially the same size and shape, gaps 452 and 462 may have different sizes and/or different shapes as long as room for at least a portion of cooling system 420 is provided. Because the total thickness of the interposer 450 and circuit board 460 may be on the order of 1.5 millimeters to three millimeters, gaps 452 and 462 may provide sufficient space for cooling system 420 to be integrated with little or no modifications to cover 402. Thus, mobile phone 400 and the components therein allow for thermal contact to be achieved between heat-generating structure 430 and cooling system 420. Further, the components have been configured to allow for cooling system 420 and the remaining components of mobile phone 400 to fit within a compact package.

Thus, cooling system 420 shares the benefits of cooling system 100, 200, and/or 300. Performance of mobile phone 400 may be improved. Further, the components of mobile phone 400 may be configured to allow cooling system 420 as well as other components of mobile phone 400 to fit within mobile phone 400. Thus, improved performance may be achieved in a very thin device.

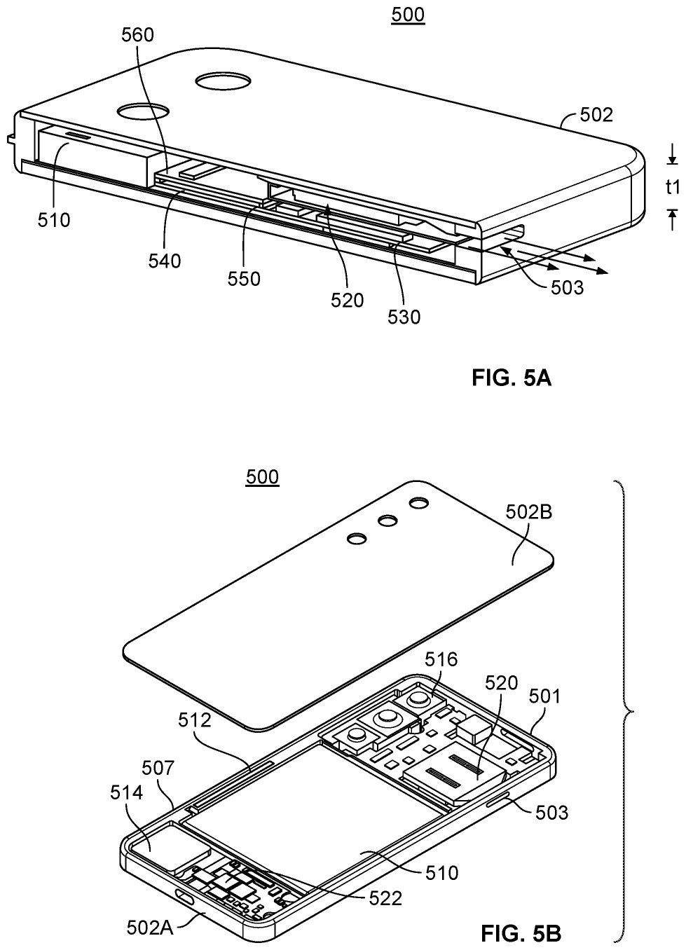

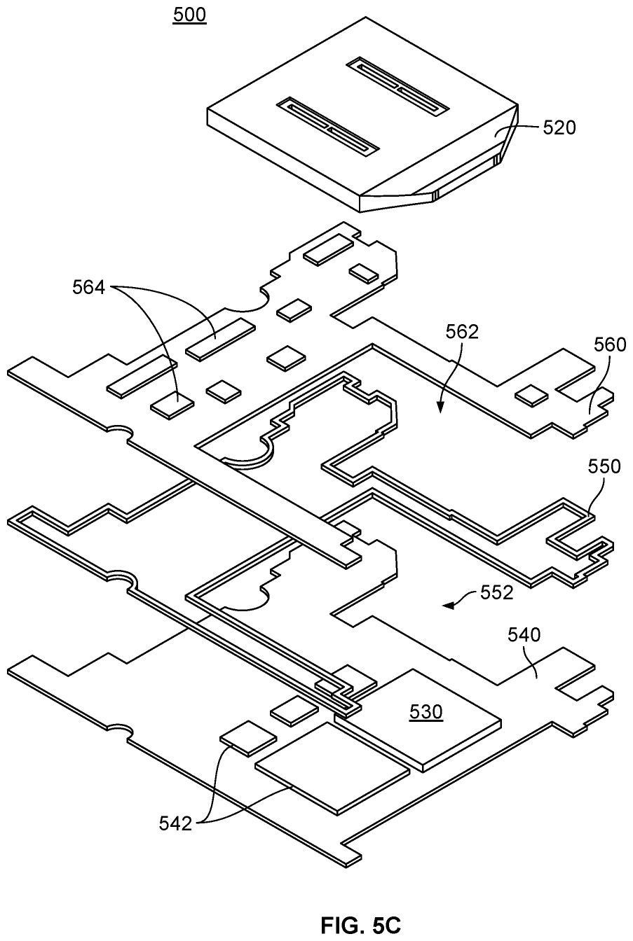

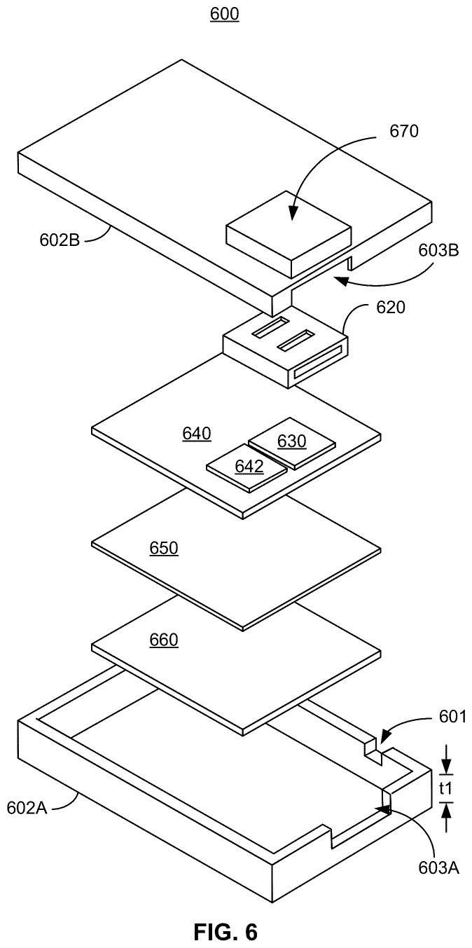

FIGS. 5A-5C depict an embodiment of active MEMS cooling system 520 integrated into mobile phone 500. FIG. 5A is a perspective view of mobile phone 500 depicting a portion of the interior. FIG. 5B is a partially exploded view of mobile phone 500. FIG. 5C is an exploded view of a portion of mobile phone 500. Referring to FIGS. 5A-5C, mobile phone 500 and cooling system 520 are analogous to mobile phone 400 and cooling system 420. Mobile phone 500 may include bottom cover 502A and top cover 502B (collectively referred to as cover 502), cooling system 520, circuit boards 540 and 560, interposer 550, and heat-generating structure 530 (e.g. a processor) that are analogous to bottom cover 402A, top cover 402B, cooling system 420, circuit boards 540 and 560, interposer 550, and heat-generating structure 420, respectively. Cover 502 includes ingress 501 and egress 503 analogous to ingress 401 and egress 403, respectively. Cover 502 defines an interior portion of mobile phone 500 having thickness t1 analogous to that described for mobile phone 400. Mobile phone 500 also has additional ingress 507. Also explicitly shown are battery 510, antenna 512, speaker 514, camera 516, additional components 542 (of which only two are labeled) coupled to circuit board 540, additional components 564 (of which only two are labeled) coupled to circuit board 560, and controller 522 for cooling system 520. Other and/or additional components may be present in some embodiments. Some components shown may be omitted in some embodiments.

Interposer 550 and circuit board 560 include gap 552 and circuit board gap 562, respectively, that are analogous to gap 452 and circuit board gap 462, respectively, of mobile phone 400. However, gaps 552 and 562 are cutouts near the perimeter of the footprint for circuit board 560 and interposer 550. Gap 552 is aligned with gap 562. Although shown as substantially the same size and shape, gaps 552 and 562 may have different sizes and/or different shapes as long as room for at least a portion of cooling system 520 is provided. As indicated in FIG. 5C, cooling system 520 may fit within gaps 552 and 562. Thus, cooling system 520 may fit within cover 502, achieve good thermal contact with heat-generating structure 530, while allowing mobile phone 500 to maintain a slim profile.

Cooling system 520 shares the benefits of cooling system 100, 200, 300, and/or 420. Performance of mobile phone 500 may be improved. Further, the components of mobile phone 500 may be configured to allow cooling system 520 as well as other components of mobile phone 500 to fit within mobile phone 500 with little or no modification to cover 502. Thus, improved performance may be achieved in a very thin device.

FIG. 6 depicts an embodiment of active MEMS cooling system 620 integrated into mobile phone 600. Mobile phone 600 and cooling system 620 are analogous to mobile phone 400 and cooling system 420. Mobile phone 600 may include bottom cover 602A and top cover 602B (collectively referred to as cover 602), cooling system 620, circuit boards 640 and 660, interposer 650, and heat-generating structure 630 (e.g. a processor) that are analogous to bottom cover 402A, top cover 402B, cooling system 420, circuit boards 640 and 660, interposer 650, and heat-generating structure 420, respectively. Although shown as a plate, interposer 650 may instead be a frame or have another configuration similar to frame 550. However, interposer 650 may not include a gap analogous to gaps 452 and 552. Similarly, circuit board 660 may not include a gap analogous to gaps 462 and 562. Although not shown, circuit board 660 may include various components. Cover 602 includes ingress 601 and egress 603 analogous to ingress 401 and egress 403, respectively. Cover 602 defines an interior portion of mobile phone 600 having thickness t1 analogous to that described for mobile phone 400. Other and/or additional components may be present in some embodiments. Some components shown may be omitted in some embodiments.

Cover 602 also includes a raised portion 670. Although raised portion 670 is shown on top cover 602B, raised portion 670 may be on bottom cover 602A. Raised portion 670 has a cavity therein in which at least a portion of cooling system 620 may reside. Although not shown, raised portion 670 may have ingress(es) to allow for fluid to be drawn in through such ingress(es). Raised portion 670 allows for cooling system 620 to be accommodated in mobile phone 600 without gaps or other changes to interposer 650 and/or circuit board 660. Thus, for mobile phone 600, changes to incorporate cooling system 620 may be made to cover 602 instead of or in addition to components contained therein. In some embodiments, changes may also be made to components, such as interposer 650, to reduce the size (e.g. height) of raised portion 670.

Cooling system 620 shares the benefits of cooling system 100, 200, 300, 420, and/or 520. Performance of mobile phone 600 may be improved. Further, the components of mobile phone 600 may be configured to allow cooling system 620 as well as other components of mobile phone 600 to fit within mobile phone 600 while substantially maintaining a small thickness. Instead, a relatively small, raised portion 670 may be added to cover 602. Thus, improved performance may be achieved in a very thin device.

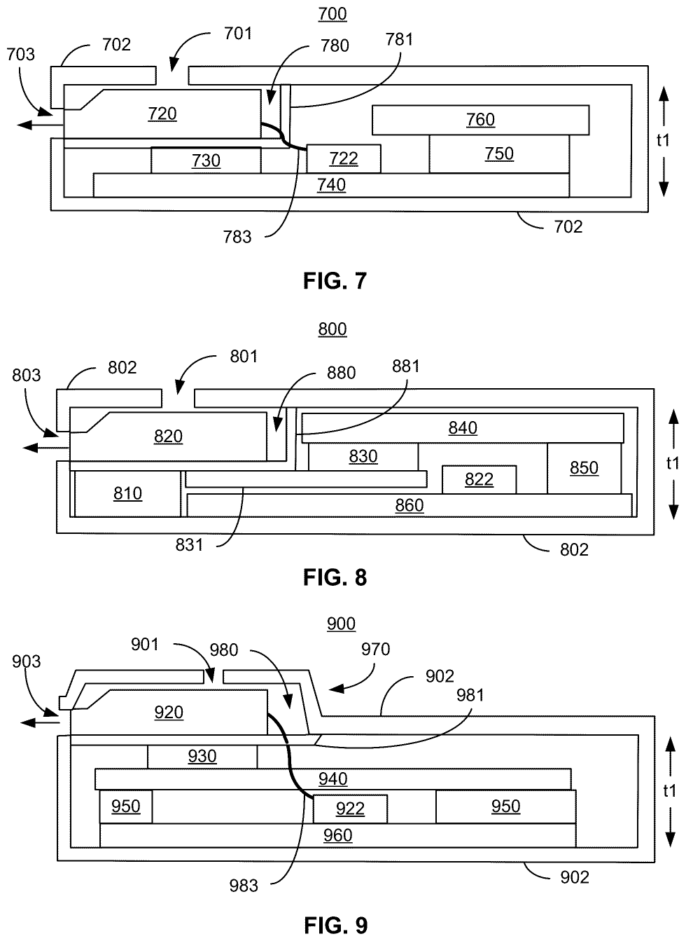

FIG. 7 depicts an embodiment of active MEMS cooling system 720 integrated into mobile phone 700. Mobile phone 700 and cooling system 720 are analogous to mobile phone 400 and cooling system 420. Mobile phone 700 may include cover 702 (which may include separate top and bottom covers that are not shown), cooling system 720, circuit boards 740 and 760, interposer 750, and heat-generating structure 730 (e.g. a processor) that are analogous to cover 402, cooling system 420, circuit boards 440 and 460, interposer 450, and heat-generating structure 420, respectively. In some embodiments, interposer 750 and circuit board 760 have gaps (not explicitly depicted) analogous to gaps 452 and 462 and gaps 552 and 562. In such embodiments, cooling system 720 may be better able to fit within cover 702. Although not shown, circuit board 760 may include various components. Cover 702 includes ingress 701 and egress 703 analogous to ingress 401 and egress 403, respectively. Although shown as being in the top, ingress 701 may be located on the side or back cover of mobile phone 700. Cover 702 defines an interior portion of mobile phone 700 having thickness t1 analogous to that described for mobile phone 400. Other and/or additional components may be present in some embodiments. Some components shown may be omitted in some embodiments.

Cooling system 720 resides in cavity 780 separated from the remainder of the interior of mobile phone 700. In the embodiments shown, wall 781 separates and seals cavity 780 from the portion of the interior in which circuit boards 740 and 760, interposer 750, and heat-generating structure 730 reside. Sealed flex connect 783 provides electrical connection between cooling system 720 and at least cooling system controller 722. Although flex connect 783 is shown as passing through wall 781, a single connect need not be used. Instead, flex connect 783 indicates electrical connection being made between cavity 780 and components within the interior of mobile phone 700 despite the presence of wall 781. Wall 781 allows for thermal connection to be made between cooling system 720 and heat generating structure 730. For example, wall 781 may include or consist of copper or thin stainless steel (e.g. not more than 100 micrometers thick) and/or a vapor chamber.

In some embodiments, cavity 780 allows for fluid, both air and water, to ingress and egress. However, the interior portion of mobile phone 700 separated from cavity 780 by wall 781 is water resistant. For example, the interior portion including components 730, 740, 750, 760, and 722 may be IP68 water resistant. Cooling system 720 may be water (and air) compatible. However, if exposed to water, cooling system 720 may be desired to be turned off by cooling system controller 722. In some embodiments, some barrier to water, such as an IP68 membrane, might also be present in ingress 701 and egress 703 to reduce the penetration of water into cavity 780.

Cooling system 720 shares the benefits of cooling system 100, 200, 300, 420, 520, and/or 620. Performance of mobile phone 700 may be improved. Further, the components of mobile phone 700 may be configured to allow cooling system 720 as well as other components of mobile phone 700 to fit within mobile phone 700 while substantially maintaining a small thickness. In addition, the interior portion of mobile phone 700 that houses heat-generating structure 730 (e.g. a processor) and other electrical components may be maintained in a water resistant environment. Thus, improved performance, reliability, and water tolerance may be achieved in a very thin device.

FIG. 8 depicts an embodiment of active MEMS cooling system 820 integrated into mobile phone 800. Mobile phone 800 and cooling system 820 are analogous to mobile phone 400 and cooling system 420. Mobile phone 800 and cooling system 820 are also more analogous to mobile phone 700 and cooling system 720. Mobile phone 800 may include cover 802 (which may include separate top and bottom covers that are not shown), cavity 880, wall 881, cooling system 820, circuit boards 840 and 860, interposer 850, and heat-generating structure 830 (e.g. a processor) that are analogous to cover 702, cavity 780, wall 781, cooling system 720, circuit boards 740 and 760, interposer 750, and heat-generating structure 720, respectively. In some embodiments, interposer 850 and circuit board 860 have gaps (not explicitly depicted) analogous to gaps 452 and 462 and gaps 552 and 562. In such embodiments, cooling system 820 may be better able to fit within cover 802. Although not shown, circuit board 860 may include various components. Cover 802 includes ingress 801 and egress 803 analogous to ingress 701 and egress 703, respectively. Cover 802 defines an interior portion of mobile phone 800 having thickness t1 analogous to that described for mobile phone 400. Also shown is battery 810 and a heat spreader 831. Other and/or additional components may be present in some embodiments. Some components shown may be omitted in some embodiments.

Cooling system 820 resides in cavity 880 that is analogous to cavity 780. Wall 881 separates cooling system 820 from the remainder of the interior of mobile phone 800 in which circuit boards 840 and 860, interposer 850, and heat-generating structure 830 reside. A flex connect (not shown) may provide electrical connection between cooling system 820 and at least cooling system controller 822. In the embodiment shown, wall 881, and thus cooling system 820, are thermally connected to heat-generating structure 830 via heat spreader 831. Wall 881 is also thermally connected to battery 810. Thus, cooling system 820 may transfer heat from heat-generating structure 830 and battery 810. Cavity 880 allows for fluid, both air and water, to ingress and egress. However, the interior portion of mobile phone 800 separated from cavity 880 by wall 881 is water resistant (e.g. IP68 water resistant). Cooling system 820 may be water (and air) compatible. However, if exposed to water, cooling system 820 may be desired to be turned off by cooling system controller 822. In some embodiments, some barrier to water, such as an IP68 membrane, might also be present in ingress 801 and egress 803 to reduce the penetration of water into cavity 880.

Cooling system 820 shares the benefits of cooling system 100, 200, 300, 420, 520, 629, and/or 720. Performance of mobile phone 800 may be improved. Further, the components of mobile phone 800 may be configured to allow cooling system 820 as well as other components of mobile phone 800 to fit within mobile phone 800 while substantially maintaining a small thickness. In addition, the interior portion of mobile phone 800 that houses heat-generating structure 830 (e.g. a processor) and other electrical components may be maintained in a water resistant environment. Thus, improved performance, reliability, and water tolerance may be achieved in a very thin device.

FIG. 9 depicts an embodiment of active MEMS cooling system 920 integrated into mobile phone 900. Mobile phone 900 and cooling system 920 are analogous to mobile phone 400 and cooling system 420. Mobile phone 900 and cooling system 920 are also more analogous to mobile phone 700 and cooling system 720. Mobile phone 900 may include cover 902 (which may include separate top and bottom covers that are not shown), cavity 980, wall 981, cooling system 920, circuit boards 940 and 960, interposer 950, and heat-generating structure 930 (e.g. a processor) that are analogous to cover 702, cavity 780, wall 781, cooling system 720, circuit boards 740 and 760, interposer 750, and heat-generating structure 720, respectively. In some embodiments, interposer 950 and circuit board 960 have gaps (not explicitly depicted) analogous to gaps 452 and 462 and gaps 552 and 562. In such embodiments, cooling system 920 may be better able to fit within cover 902. Although not shown, circuit board 960 may include various components. Cover 902 includes ingress 901 and egress 903 analogous to ingress 701 and egress 703, respectively. Cover 902 defines an interior portion of mobile phone 900 having thickness t1 analogous to that described for mobile phone 400. Other and/or additional components may be present in some embodiments. Some components shown may be omitted in some embodiments.

Cooling system 920 resides in cavity 980 that is analogous to cavities 780 and 880. Cavity 980 is also at least partially formed by raised portion 970 of cover 902. Raised portion 970 is analogous to raised portion 670. Although raised portion 970 is shown on top, raised portion 970 may be on the bottom. In some embodiments, only a portion of cavity 980 is formed by raised portion 970. Use of raised portion 970 for cavity 980 allows for cooling system 920 to be accommodated in mobile phone 900 while limiting or avoiding gaps or other changes to interposer 950 and/or circuit board 960. Thus, for mobile phone 900, changes to incorporate cooling system 920 may be made to cover 902 instead of or in addition to components contained therein.

Wall 981 separates cooling system 920 from the remainder of the interior of mobile phone 900 in which circuit boards 940 and 960, interposer 950, and heat-generating structure 930 reside. Flex connect 983, which is analogous to flex connect 783, may provide electrical connection between cooling system 920 and at least cooling system controller 922. In the embodiment shown, wall 981, and thus cooling system 920, are thermally connected to heat-generating structure 930. Cavity 980 allows for fluid, both air and water, to ingress and egress. However, the interior portion of mobile phone 900 separated from cavity 980 by wall 981 is water resistant (e.g. IP68 water resistant). Cooling system 920 may be water (and air) compatible. However, if exposed to water, cooling system 920 may be desired to be turned off by cooling system controller 922. In some embodiments, some barrier to water, such as an IP68 membrane, might also be present in ingress 901 and egress 903 to reduce the penetration of water into cavity 980.

Cooling system 920 shares the benefits of cooling system 100, 200, 300, 420, 520, and/or 620. Performance of mobile phone 900 may be improved. Further, the components of mobile phone 900 may be configured to allow cooling system 920 as well as other components of mobile phone 900 to fit within mobile phone 900 while substantially maintaining a small thickness. In addition, the interior portion of mobile phone 900 that houses heat-generating structure 930 (e.g. a processor) and other electrical components may be maintained in a water resistant environment. Thus, improved performance, reliability, and water tolerance may be achieved in a very thin device.

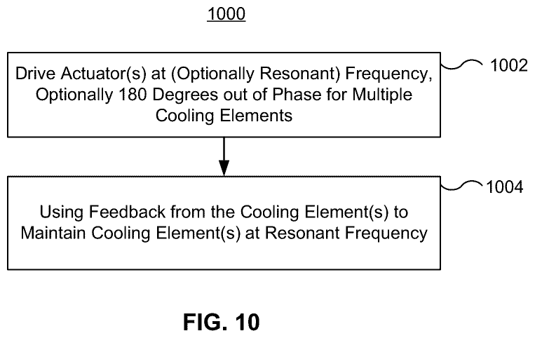

FIG. 10 is a flow chart depicting an exemplary embodiment of method 1000 for operating a cooling system. Method 1000 may include steps that are not depicted for simplicity. Method 1000 is described in the context of cooling systems 100, 300, 420, 520, 620, 720 and/or 820. However, method 1000 may be used with other cooling systems including but not limited to systems and cells described herein.

One or more of the actuator(s) in a cooling system is actuated to vibrate, at 1002. At 1002, an electrical signal having the desired frequency is used to drive the actuator(s). In some embodiments, the actuators are driven at or near structural and/or acoustic resonant frequencies at 1002. The driving frequency may be 15 kHz or higher. In some embodiments, the driving signal may be 20 kHz or higher. If multiple actuators are driven at 1002, the cooling actuators may be driven out-of-phase. In some embodiments, the actuators are driven substantially at one hundred and eighty degrees out of phase. Further, in some embodiments, individual actuators are driven out-of-phase. For example, different portions of an actuator may be driven to vibrate in opposite directions (i.e. analogous to a seesaw). In some embodiments, individual actuators may be driven in-phase (i.e. analogous to a butterfly). In addition, the drive signal may be provided to the anchor(s), the actuator(s), or both the anchor(s) and the actuator(s). Further, the anchor may be driven to bend and/or translate.

Feedback from the piezoelectric actuator(s) is used to adjust the driving current, at 1004. In some embodiments, the adjustment is used to maintain the frequency at or near the acoustic and/or structural resonant frequency/frequencies of the actuator(s) and/or cooling system. Resonant frequency of a particular actuator may drift, for example due to changes in temperature. Adjustments made at 1004 allow the drift in resonant frequency to be accounted for.

For example, piezoelectric actuators within active cooling system(s) 420 and/or 520 may be driven at or near their structural resonant frequency/frequencies, at 1002. Such actuators may correspond to cooling element 120. This resonant frequency may also be at or near the acoustic resonant frequency for the top chamber 140. This may be achieved by driving piezoelectric layer(s) in anchor 160 and/or piezoelectric layer(s) in actuator 120. At 1004, feedback is used to maintain actuators 120 at resonance and, in some embodiments in which multiple actuators are driven, one hundred and eighty degrees out of phase. Thus, the efficiency of actuator 120 in driving fluid flow through active cooling system(s) 420 and/or 520 may be maintained. In some embodiments, 1004 includes sampling the current through actuator 120 and/or the current through anchor 160 and adjusting the current to maintain resonance and low input power.

Consequently, active cooling system(s) 420, 520, 620, 720, 820, and/or 920 may be operated to drive fluid through a thin computing device. Thus, thin computing devices may be more efficiently cooled. Thermal management and performance of such thin computing devices may be enhanced.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A mobile phone, comprising:
a cover defining an interior portion of the mobile phone;
a circuit board to which a heat-generating structure is coupled, the circuit board being within the interior portion;
a cooling system including at least one active cooling cell, the heat-generating structure being thermally coupled with the cooling system, the at least one active cooling cell being configured to utilize vibrational motion to drive a fluid for transferring heat from the heat-generating structure, the cooling system being contained by the cover; and
wherein at least one of the mobile phone includes an interposer, the cover includes a raised portion, or the mobile phone includes a cavity therein, the interposer being coupled to the circuit board and including a gap configured such that a first portion of the cooling system thermally coupled with the heat-generating structure resides within the gap, the raised portion of the cover being configured such that a second portion of the cooling system resides in the raised portion, the cavity including the cooling system therein, separating the cooling system from the interior portion of the mobile phone, and configured such that the interior portion is water resistant.

2. The mobile phone of claim 1, wherein the mobile phone includes the interposer and wherein the mobile phone further includes:
an additional circuit board, the interposer being coupled to and between the circuit board and the additional circuit board.

3. The mobile phone of claim 2, wherein the additional circuit board includes a circuit board gap aligned with the gap of the interposer such that the first portion of the cooling system fits within the circuit board gap.

4. The mobile phone of claim 1, wherein the mobile phone includes the cavity and wherein the cavity is IP68 water resistant.

5. The mobile phone of claim 4, further comprising:
a flex connector coupled with the cooling system such that the cooling system is electrically connected with the interior portion of the mobile phone.

6. The mobile phone of claim 1, wherein the cooling system has a total height not exceeding 3.5 millimeters.

7. The mobile phone of claim 6, wherein the total height is not less than 1 millimeter and not exceeding three millimeters.

8. The mobile phone of claim 1, wherein the heat-generating structure includes a processor for the mobile phone.

9. The mobile phone of claim 1, wherein the cooling system further includes a heat sink, the heat sink being thermally coupled with the heat-generating structure.

10. The mobile phone of claim 1, wherein the cooling system includes a first cooling cell and a second cooling cell.

11. The mobile phone of claim 1, further comprising:
a battery, the cooling system being configured to utilize the vibrational motion to transfer the heat from the battery.

12. The mobile phone of claim 1, wherein each of the at least one active cooling cell includes at least one cooling element configured to undergo the vibrational motion to drive the fluid toward the heat-generating structure.

13. The mobile phone of claim 12, wherein the cooling element has a first cantilevered arm, a second cantilevered arm, and a central portion between the first cantilevered arm and the second cantilevered arm, the first cantilevered arm and the second cantilevered arm undergoing the vibrational motion.

14. The mobile phone of claim 13, wherein each of the at least one active cooling cell further includes:
a top plate having at least one vent therein; and
an orifice plate including a plurality of orifices therein, the at least one cooling element being between the top plate and the orifice plate, the vibrational motion drawing the fluid through the vent, directing the fluid past the cooling element, and driving the fluid out of the plurality of orifices.

15. A mobile phone, comprising:
a front cover;
a back cover, an interior of the mobile phone being defined between the front cover and the back cover;
a heat-generating structure;
a circuit board including a plurality of computing components thereon; and
a cooling system including at least one active cooling cell, the at least one active cooling cell being configured to utilize vibrational motion to drive a fluid for removing heat from the heat-generating structure;
wherein at least one of the mobile phone includes an interposer, at least one of the front cover or the back cover includes a raised portion, or the cover includes a cavity therein, the interposer being coupled to the circuit board and including a gap configured such that a first portion of the cooling system thermally coupled with the heat-generating structure resides within the gap, the raised portion of the cover being configured such that a second portion of the cooling system resides in the raised portion, the cavity including the cooling system therein, separating the cooling system from an interior portion of the mobile phone including the circuit board, and configured such that the interior portion is water resistant.

16. The mobile phone of claim 15, wherein the mobile phone includes the interposer and wherein the mobile phone further includes:
an additional circuit board, the interposer being coupled to and between the circuit board and the additional circuit board, the additional circuit board including a circuit board gap aligned with the gap of the interposer such that the first portion of the cooling system fits within the circuit board gap.

17. The mobile phone of claim 15, wherein the mobile phone includes the cavity and wherein the cavity is IP68 water resistant.

18. The mobile phone of claim 15, wherein the heat-generating structure is at least one of a processor mounted on the circuit board or a battery.

19. A method for cooling a mobile phone having a cover defining an interior portion of the mobile phone, the method comprising:
driving a plurality of active cooling cells in a cooling system of the mobile phone, the mobile phone further including a circuit board within the interior portion and a heat-generating structure thermally coupled with the cooling system, the plurality of active cooling cells being configured to utilize vibrational motion to drive a fluid for transferring heat from the heat-generating structure;
wherein at least one of the mobile phone includes an interposer, the cover includes a raised portion, or the mobile phone includes a cavity therein, the interposer being coupled to the circuit board and including a gap configured such that a first portion of the cooling system thermally coupled with the heat-generating structure resides within the gap, the raised portion of the cover being configured such that a second portion of the cooling system resides in the raised portion, the cavity including the cooling system therein, separating the cooling system from the interior portion of the mobile phone, and configured such that the interior portion is water resistant.

20. The method of claim 19, wherein the driving further includes:
driving the plurality of active cooling cells such that the vibrational motion is substantially at a structural resonance for the plurality of active cooling cells and substantially at a fluidic resonance for the plurality of active cooling cells.
